(19) United States
(12) Patent Application Publication
(10) Pub. No.: US 2025/0201526 A1
(43) Pub. Date: Jun. 19, 2025

(54) METHODS AND SYSTEMS FOR DEPOSITING A LAYER

(71) Applicant: ASM IP Holding B.V., Almere (NL)

(72) Inventors: Daniele Piumi, Etterbeek (BE); Pamela Rene Fischer, Portland, OR (US)

(21) Appl. No.: 19/055,082

(22) Filed: Feb. 17, 2025

Related U.S. Application Data
(62) Division of application No. 17/544,167, filed on Dec. 7, 2021, now Pat. No. 12,255,053.
(60) Provisional application No. 63/123,626, filed on Dec. 10, 2020.

(51) Int. Cl. H01J 37/32; C23C 16/44; C23C 16/455; C23C 16/458; C23C 16/46; C23C 16/509; C23C 16/52

(52) U.S. Cl. CPC H01J 37/32449; C23C 16/4408; C23C 16/45525; C23C 16/45565; C23C 16/4586; C23C 16/46; C23C 16/509; C23C 16/52; H01J 37/32128; H01J 37/32724; H01J 37/32935; H01J 2237/332

(57) ABSTRACT

Plasma-assisted methods for depositing materials and related systems are described. The methods described herein comprise ending a deposition process when a plasma characteristic matches a pre-determined criterion.

### CROSS-REFERENCE TO RELATED APPLICATIONS

This application is a divisional of, and claims priority to, U.S. patent application Ser. No. 17/544,167 filed Dec. 7, 2021 titled METHODS AND SYSTEMS FOR DEPOSITING A LAYER; which claims priority to U.S. Provisional Patent Application Ser. No. 63/123,626 filed Dec. 10, 2020 titled METHODS AND SYSTEMS FOR DEPOSITING A LAYER, the disclosures of which are hereby incorporated by reference in their entirety.

### FIELD OF INVENTION

The present disclosure generally relates to systems and methods suitable for executing deposition processes such as chemical vapor deposition processes and atomic layer deposition processes.

### BACKGROUND OF THE DISCLOSURE

Vapor phase deposition processes are ubiquitously used in semiconductor device manufacture. Various deposition processes require a pre-determined amount of material to be deposited. This is the case, for example, in processes for filling a recess, trench, or gap in a substrate. Other processes in which a pre-determined amount of material is to be deposited include depositions of dielectric materials. However, it continues to be challenging to repeatable deposit a pre-determined amount of material, especially when tradeoffs are made with process speed. Therefore, there remains a need for methods and devices for repeatably depositing a pre-determined amount of material.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Described herein is a method for depositing a layer on a substrate. The method comprising providing a system. The system comprises a reaction chamber. The reaction chamber comprises a substrate support and an upper electrode. The substrate support comprises a lower electrode. The system further comprises a radio frequency power source. The radio frequency power source is arranged for generating a radio frequency power waveform. The method further comprises positioning a substrate on the substrate support and executing a deposition process. The deposition process comprises providing one or more gaseous precursors to the reaction chamber, generating a plasma in the reaction chamber by means of the radio frequency power waveform, and monitoring a monitored plasma characteristic. The deposition process is ended when the monitored plasma characteristic matches a pre-determined criterion.

In some embodiments, the monitored plasma characteristic comprises the radio frequency power waveform, and the pre-determined criterion comprises a spectral distribution of the radio frequency power waveform.

In some embodiments, the spectral distribution of the radio frequency power waveform comprises a fundamental frequency and an nth overtone, the fundamental frequency having a fundamental frequency amplitude and the nth overtone having an nth overtone amplitude, and the deposition process is ended when a ratio of the nth overtone amplitude and the fundamental frequency amplitude exceeds a pre-determined value.

In some embodiments, the spectral distribution of the radio frequency power waveform comprises a fundamental frequency and an nth overtone. The fundamental frequency has a fundamental frequency amplitude and the nth overtone has an nth overtone amplitude. The deposition process can be ended when a ratio of the fundamental frequency amplitude and the nth overtone amplitude exceeds a pre-determined value.

In some embodiments, the monitored plasma characteristic comprises a monitored spectral distribution of the radio frequency power waveform, and the pre-determined criterion comprises a similarity score between the monitored spectral distribution of the radio frequency power waveform and a pre-determined spectral distribution.

In some embodiments, the monitored plasma characteristic comprises a matching impedance of an impedance matching block, and the impedance matching block is arranged for matching an impedance of the radio frequency power source to a load.

In some embodiments, the matching impedance is frequency dependent, and the pre-determined criterion comprises a similarity score between the matching impedance and a pre-determined frequency-dependent reference impedance.

In some embodiments, the deposition process comprises continuously providing one or more gaseous precursors to the reaction chamber, and the deposition process comprises continuously generating a plasma in the reaction chamber.

In some embodiments, the deposition process is a cyclical deposition process comprising a plurality of alternating cycles that each comprise two or more steps.

In some embodiments, the cycles comprise a step of contacting the substrate with a first precursor, and a step of contacting the substrate with a second precursor.

In some embodiments, the step of contacting the substrate with the first precursor and the step of contacting the substrate with the second precursor are separated by an intra-cycle purge.

In some embodiments, subsequent cycles are separated by an inter-cycle purge.

Further described herein is a system that comprises a reaction chamber, a radio frequency power source, a gas injection system, at least one gas source, an exhaust, and a controller. The reaction chamber comprises a substrate support and an upper electrode. The substrate support comprises a lower electrode. The radio frequency power source is arranged for generating a radio frequency power waveform. The gas injection system is fluidly coupled to the reaction chamber. The at least one gas source is arranged for introducing a precursor and optionally a carrier gas in the reaction chamber. The controller comprises a gas flow controlling unit, a memory, a plasma control and measurement unit, and a comparing unit. The gas flow controlling unit is arranged to control gas flow into the gas injection system. The memory is arranged to store a pre-determined plasma characteristic. The plasma control and measurement unit is arranged for causing the system to generate a radio frequency plasma in the reaction chamber by means of the radio frequency power waveform. The plasma control and measurement unit is further arranged to monitor the radio frequency plasma. Thus, a monitored plasma characteristic is obtained. The comparing unit is arranged for comparing the monitored plasma characteristic with the pre-determined plasma characteristic stored in the memory. The controller is configured to end a deposition process when the comparing unit indicates that the monitored plasma characteristic matches a pre-determined criterion.

In some embodiments, the controller is arranged for causing the system to carry out a method as described herein.

In some embodiments, the upper electrode comprises a showerhead injector.

In some embodiments, the showerhead injector is a dual channel showerhead injector comprising a first set of channels and a second set of channels.

In some embodiments, the lower electrode is grounded, the upper electrode is electrically connected to the radio frequency power source, and the upper electrode is electrically connected to the plasma control and measurement unit.

In some embodiments, the system further comprises a wall heater for heating a wall of the reaction chamber.

In some embodiments, the substrate support comprises a heater.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 shows an embodiment of a system (100) as disclosed herein.

FIG. 2 shows parts of an embodiment of a system (100) as disclosed herein.

FIG. 3 shows an equivalent circuit of the components shown in FIG. 2.

FIG. 4 shows three stages of a material deposition process that can be executed by means of a method as disclosed herein.

FIG. 5 comprises four panels: Panel a) schematically shows how the spectral composition of the radio frequency signal by which the plasma is generated changes in time. Panel b) schematically shows discrete overtones in a frequency spectrum of the radio frequency signal by which the plasma is generated at the beginning of a deposition process. Panel c) schematically shows discrete overtones in a frequency spectrum of the radio frequency signal by which the plasma is generated at the end of a deposition process. Panel d) schematically shows a continuous frequency spectrum of the radio frequency signal, in which the overtones are labeled.

FIG. 6 schematically shows an exemplary embodiment of a plasma control and measurement unit (320).

FIG. 7 illustrates an embodiment of a method for depositing a material on a substrate.

FIG. 8 illustrates a further embodiment of a method for depositing a material on a substrate as described herein.

FIG. 9 schematically shows an exemplary embodiment of a plasma control and measurement unit (900).

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

Described herein are methods and related systems that can be used, for example, for depositing materials in a repeatable way.

In some embodiments, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. Alternatively, a “reactant” may refer to a compound that reacts with a surface of a substrate to form a volatile reaction product. Thus, “reactants” may be used in both deposition processes or etching processes, or both.

In some embodiments, “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material. Exemplary substrates include wafers such as silicon wafers, e.g., 200 mm wafers, 300 mm wafers, or 450 mm wafers.

In some embodiments, “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

In some embodiments, “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

In some embodiments, “atomic layer deposition” (ALD) can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy, molecular beam epitaxy (MBE), gas source MBE, organometallic MBE, and chemical beam epitaxy, when performed with alternating pulses of precursor(s)/reactive gas(es), and purge (e.g., inert carrier) gas(es).

In some embodiments, “atomic layer etch” can refer to a vapor etching process in which etching cycles, typically a plurality of consecutive etching cycles, are conducted in a process chamber. The term “atomic layer deposition” can include processes designated by related terms.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the term “comprising” indicates that the embodiment it refers to includes those features, but it does not exclude the presence of other features, as long as they do not render the corresponding embodiment unworkable. On the other hand, “consisting of” indicates that no further features are present in the embodiment concerned apart from the ones following said wording, except optional further features which do not materially affect the essential characteristics of the corresponding embodiment. It shall be understood that the term “comprising” includes the meaning of the term “consisting of.”

Described herein is a method for depositing a layer on a substrate. The method employs a system comprising a reaction chamber and a radio frequency power source. The reaction chamber comprises a substrate support and an upper electrode. The substrate support comprises a lower electrode. The radio frequency power source is arranged for generating a radio frequency power signal, or radio frequency power waveform. The method comprises positioning a substrate on a substrate support. Suitable substrates include semiconductor wafers, e.g., silicon wafers such as p-type silicon wafers. The substrate can have any dimension. An exemplary substrate is circular and has a diameter of 200 mm, 300 mm, or 450 mm. The method further comprises executing a deposition process. The deposition process comprises providing one or more gaseous precursors to the reaction chamber and generating a plasma in the reaction chamber. Suitably, the plasma can be generated in the reaction chamber by means of the radio frequency power waveform. During the deposition process, at least one plasma characteristic is monitored, and the deposition process is ended when the monitored plasma characteristic matches a pre-determined criterion.

In some embodiments, the radio frequency power waveform as such can be used as a monitored plasma characteristic. In such embodiments, its frequency distribution, i.e., the spectral distribution of the radio frequency power waveform, can be used as a pre-determined criterion. In other words, and in some embodiments, the present methods can comprise ending a deposition process when the frequency spectrum of the radio frequency power waveform matches a pre-determined frequency spectrum to a certain extent. The spectral distribution of the radio frequency power waveform can be obtained by techniques which are known as such in the art, for example by means of a Fast Fourier Transform (FFT).

In some embodiments, spectral peaks in the spectral distribution of the radio frequency power waveform can be used for ending the deposition process. In particular, the spectral distribution of the radio frequency power waveform can comprise a fundamental frequency and a plurality of overtones. The plurality of overtones comprise an nth overtone. A ratio of the amplitude of the nth overtone and the amplitude of the fundamental frequency can be a suitable stop criterion. Thus, in some embodiments, the deposition process is ended when a ratio of the nth overtone amplitude and the fundamental frequency amplitude exceeds a pre-determined value. Alternatively, the deposition can, in some embodiments, be ended when the deposition process is ended when a ratio of the fundamental frequency amplitude and the nth overtone amplitude exceeds a pre-determined value. Alternatively, and in some embodiments, the deposition can be ended when a ratio of the fundamental frequency amplitude and the nth overtone amplitude is out of the bounds of a pre-determined range.

In some embodiments, the monitored plasma characteristic comprises a spectral distribution of the radio frequency power waveform. In such embodiments, the pre-determined criterion suitably comprises a similarity score between the spectral distribution of the radio frequency power waveform and a pre-determined spectral distribution. The similarity score can be computed, for example, by subtracting the spectral distribution of the radio frequency power waveform from the pre-determined spectral distribution, and integrating this difference to obtain a similarity score. In some embodiments, the deposition process is ended when this similarity score reaches a pre-determined value. In some embodiments, the deposition process is ended when this similarity score, as a function of time, reaches a stationary point. In other words, and in some embodiments, the deposition process is ended when the absolute value of the rate of change of the similarity score with time drops below a pre-determined value.

In some embodiments, the deposition process can be ended based on a matching impedance, for example a matching impedance of an impedance matching block. It shall be understood that the matching impedance is used for matching an impedance of the radio frequency power source to a load. The matching impedance is typically frequency dependent, and in some embodiments, the deposition is ended based on a similarity score between the matching impedance and a pre-determined frequency-dependent reference impedance. The similarity score can be computed, for example, by subtracting the matching impedance from the pre-determined frequency-dependent reference impedance, and integrating this difference to obtain a similarity score. In some embodiments, the deposition process is ended when this similarity score reaches a pre-determined value. In some embodiments, the deposition process is ended when this similarity score, as a function of time, reaches a stationary point. In other words, and in some embodiments, the deposition process is ended when the absolute value of the rate of change of the similarity score with time drops below a pre-determined value.

In some embodiments, the deposition process comprises continuously providing one or more gaseous precursors to the reaction chamber. In such embodiments, the deposition process suitably comprises continuously generating a plasma in the reaction chamber. Alternatively, the deposition process can comprise generating a pulsed plasma in the reaction chamber. In other words, the deposition process can comprise generating an intermittent plasma in the reaction chamber.

In some embodiments, the deposition process is a cyclical deposition process. A suitable cyclical deposition process comprises a plurality of alternating cycles. A cycle can include two or more steps. In some embodiments, the cycle comprises a step of contacting the substrate with a first precursor, and a step of contacting the substrate with a second precursor. Optionally, the step of contacting the substrate with the first precursor and the step of contacting the substrate with the second precursor are separated by an intra-cycle purge. Additionally or alternatively, subsequent cycles can, in some embodiments, be separated by an inter-cycle purge.

Further described herein is a system that comprises a reaction chamber, a radio frequency power source, a gas injection system, at least one gas source, an exhaust, and a controller.

The reaction chamber comprises a substrate support and an upper electrode. The substrate support comprises, in turn, a lower electrode.

The gas injection system is fluidly coupled to at the reaction chamber. The at least one gas source is arranged for introducing a precursor in the reaction chamber. Optionally, the precursor is introduced into the reaction chamber by means of a carrier gas.

The exhaust can be suitably arranged for removing unused precursors, carrier gasses, and reaction products. The exhaust can suitably be in fluid connection with a gas evacuating means such as a pump, e.g., a turbo pump, and/or a cold trap. The gas evacuating means may not be comprised in the presently described systems.

The radio frequency power source is arranged for generating a radio frequency power waveform.

In some embodiments, the controller is configured to control gas flow into the gas injection system. Also, the controller can comprise a plasma control and measurement unit which is arranged for causing the system to generate a radio frequency plasma in the reaction chamber. The controller can be further arranged for causing the system to carry out a method as disclosed herein.

In some embodiments, the controller further comprises a gas flow controlling unit, a memory, a plasma control and measurement unit, and a comparing unit. The gas flow controlling unit is suitably arranged to control gas flow into the gas injection system. The memory can be suitably arranged to store a pre-determined plasma characteristic. The plasma control and measurement unit is arranged for causing the system to generate a radio frequency plasma in the reaction chamber by means of the radio frequency power waveform. The plasma control and measurement unit is further arranged to monitor the radio frequency plasma to obtain a monitored plasma characteristic. The comparing unit is arranged to compare the monitored plasma characteristic with the pre-determined plasma characteristic stored in the memory. The controller is programmed to end the deposition process when the comparing unit indicates that the monitored plasma characteristic matches a pre-determined criterion. The controller can be further arranged for causing the system to carry out a method as disclosed herein.

The controller can include modules such as a software or hardware component, e.g., a FPGA or ASIC, which performs certain tasks. It shall be understood that where the controller includes a software component to perform a certain task, the controller is programmed to perform that particular task. A module can advantageously be configured to reside on the addressable storage medium, i.e., memory, of the controller and can be configured to control, for example, any specific function of the system.

In some embodiments, a showerhead injector serves as upper electrode. Suitable showerhead injectors include dual channel showerhead injectors comprising a first set of channels and a second set of channels. Thus, two types of precursors can be readily provided to the reaction chamber, even when those precursors might react with each other under conditions present in the gas injection system. An exemplary dual channel showerhead injector is described in U.S. Pat. No. 7,601,223. In some embodiments, the system comprises additional injectors for injecting an inert gas, such as inert gas injectors, e.g., dilution gas injectors, or seal gas injectors. Suitable inert gasses include the noble gasses.

In some embodiments, the lower electrode is grounded, and the upper electrode is electrically connected to the radio frequency power source, and to the plasma control and measurement unit. Alternatively, and in some embodiments, the upper electrode can be grounded, and the lower electrode is electrically connected to the radio frequency power source, and to the plasma control and measurement unit.

In some embodiments, the system further comprises wall heater for heating the walls of the reaction chamber. In some embodiments, the walls of the reaction chamber may be heated to a temperature of at least 50° C. to at most 1000° C., or to a temperature of at least 100° C. to at most 800° C., or to a temperature of at least 400° C. to at most 700° C., e.g. to a temperature of 600° C., e.g. to a temperature of 500° C. Thus, the temperature of the walls of the reaction chamber can be effectively controlled, and consequentially, the sticking coefficient of gasses such as precursors or reactants used in the reaction chamber can be controlled as well.

In some embodiments, the reaction chamber is insulated, e.g., by means of double wall insulation. Reaction chamber insulation can advantageously improve temperature control in the reaction chamber. Additionally or alternatively, reaction chamber insulation can reduce heat losses to the environment. In some embodiments, an outer surface of the reaction chamber can be cooled by means of a cooling jacket, e.g., by means of a cooling jacket comprising water.

In some embodiments, the substrate support further comprises a heater. Doing so can advantageously enhance temperature control.

The systems described herein may, in some embodiments, further comprise a load lock and/or a wafer handling system. Accordingly, when a wafer, e.g., a semiconductor wafer such as a silicon wafer, is used as a substrate, the substrate can be efficiently and optionally automatically moved from a loading station, i.e., load lock, to the reaction chamber.

In some embodiments, the system further comprising a hull which surrounds the reaction chamber. The hull can comprise, for example, a temperature-resistant material such as steel.

In some embodiments, the system comprises one or more heated gas lines. In some embodiments, the heated gas lines are heated to a temperature which is below the temperature of the reaction chamber. In some embodiments, the heated gas lines are heated to a temperature which is higher than the temperature of a precursor source comprised in the system. In some embodiments, the heated gas lines are heated to a temperature of at least 50° C. to at most 1000° C., or to a temperature of at least 100° C. to at most 600° C., or to a temperature of at least 150° C. to at most 400° C., e.g., to a temperature of 200°° C.

In some embodiments, the reaction chamber is maintained at a pressure of at least 1.10⁻¹¹ mbar to at most 1.10⁻² mbar, or at a pressure of at least 1.10⁻¹⁰ mbar to at most 1.10⁻³ mbar, or at a pressure of at least 1.10⁻⁹ mbar to at most 1.10⁻⁴ mbar, or at a pressure of at least 1.10⁻⁸ mbar to at most 1.10⁻⁵ mbar, or at a pressure of at least 1.10⁻⁷ mbar to at most 1.10⁻⁶ mbar.

In some embodiment, the system is configured for maintaining the substrate at a temperature of at least 25° C. to at most 600° C., or at a temperature of at least 50° C. to at most 500° C., or at a temperature of at least 100° C. to at most 400° C., or at a temperature of at least 200°° C. to at most 300° C. Heating the substrate can be done, for example, by means of a substrate heater comprised in the substrate support. Additionally or alternatively, the substrate can be heated by means of a heater comprised in the reaction chamber, e.g. to a temperature of at least 25° C. to at most 600° C., or to a temperature of at least 50° C. to at most 500°° C., or to a temperature of at least 100°° C. to at most 400° C., or to a temperature of at least 200°° C. to at most 300° C.

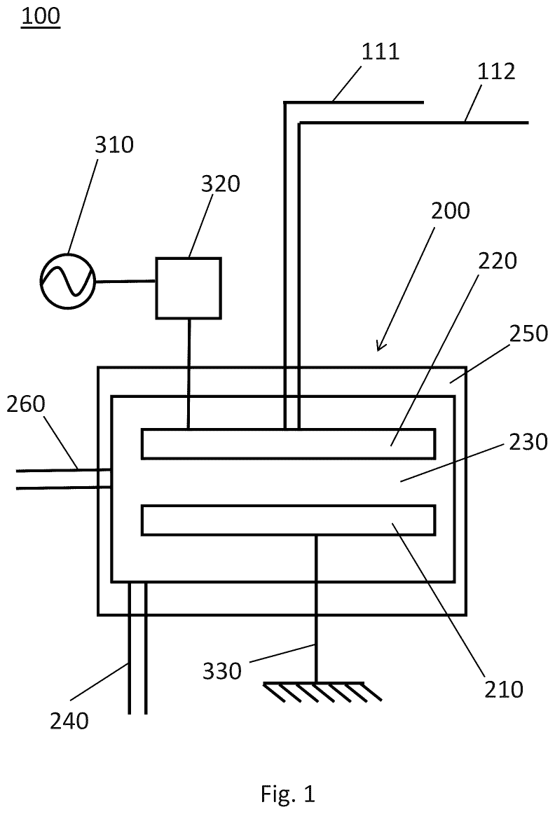

FIG. 1 shows an embodiment of a system (100) as disclosed herein. The system (100) can be used for vapor deposition processes such as plasma enhanced atomic layer deposition and plasma enhanced chemical vapor deposition. The system (100) comprises a reaction chamber (200). The reaction chamber (200) is comprised in an outer chamber (250). The reaction chamber (200) comprises a lower conductive flat-plate electrode (210), and an upper conductive flat-plate electrode (220). The lower flat-plate electrode (210) suitably serves as a substrate support. The upper flat-plate electrode (220) can suitably serve as a gas injector, i.e., as a showerhead injector, for providing one or more reaction gasses, e.g., precursors and/or reactants, to the reaction chamber (200). The one or more reaction gasses can be provided to the upper flat-plate electrode (220) by means of one or more gas lines, e.g., by means of a first gas line (111) and a second gas line (112). Unused reaction gasses, carrier gasses, reaction products, and the like can be removed from the reaction chamber (200) by means of an exhaust (240). Optionally, the system (100) comprises one or more additional gas inlets (260) for providing further gasses to the reaction chamber (200). Disposed in the reaction chamber (200), and in particular substantially between the lower flat-plate electrode (210) and the upper flat-plate electrode (220), is a reaction zone (230). In the reaction zone (230), reactive species can be formed by means of a plasma. The plasma can be generated by operationally connecting an RF power source (310), i.e. an electrical power source that produces electrical power in the form of an alternating current with a frequency in the radio frequency (RF) range, with the upper flat plate electrode (220), and by grounding the lower flat-plate electrode (210) by means of an electrical ground (330). Alternatively (embodiment not shown), a plasma can be generated in the reaction zone by operationally connecting an RF power source to the lower flat plate electrode, and by grounding the upper flat-plate electrode by means of an electrical ground. The system (100) comprises a plasma control and measurement unit (320) which is arranged for controlling and measuring one or more properties of a plasma which can be generated between the lower flat-plate electrode (210) and the upper flat-plate electrode (220). In some embodiments, the plasma control and measurement unit (320) is comprised in a controller. The controller can further comprise electronic circuitry and software to selectively operate valves, manifolds, heaters, pumps and other components included in the system (100). Such circuitry and components operate to introduce precursors, reactants, and/or purge gases from their respective sources. In some embodiments, the controller can control timing of gas pulse sequences, temperature of the substrate and/or reaction chamber, pressure within the reaction chamber, and various other operations to provide proper operation of the system (100). The controller can include modules such as a software or hardware component, e.g., a FPGA or ASIC, which performs certain tasks. A module can advantageously be configured to reside on the addressable storage medium of the controller and be configured to execute one or more processes. Various configurations of the system are possible, including various numbers and kinds of precursor sources, plasma gas sources, and purge gas sources.

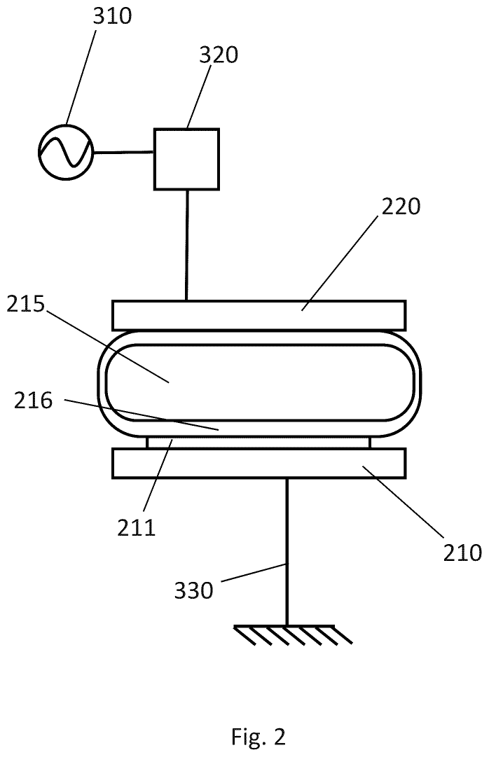

FIG. 2 shows parts of an embodiment of a system (100) as disclosed herein, and how they work together to generate a plasma (215). In particular, FIG. 2 shows a plasma (215) which is generated between a substrate (211) positioned on a lower conductive flat-plate electrode (210) on the one hand, and an upper conductive flat-plate electrode (220) on the other hand. A plasma sheath (216) surrounds the plasma (215). The lower conductive flat-plate electrode (210) is electrically grounded by means of an electrical ground (330). The upper conductive flat-plate electrode (220) is electrically connected to an RF power source (310). The upper conductive flat-plate electrode (220) is also electrically connected to a plasma control and measurement unit (320). The plasma control and measurement unit (320) contains an impedance matching block comprising electronic circuitry and is arranged for providing a control impedance that matches the combined input impedance of the plasma control and measurement unit (320) and the aforementioned elements on the one hand; i.e. the combined impedance of the plasma control and measurement unit (320), upper flat-plate electrode (220), the lower flat-plate electrode (210), the plasma (215), the plasma sheath (216), and the substrate (211); and the output impedance of the RF power source (310) on the other hand. It shall be understood that control impedances as such are known in the art, and can be colloquially named “matching boxes.” The plasma control and measurement unit (320) further comprises an impedance measurement block, or data acquisition module, which is arranged for measuring the impedance of the impedance matching block. Note that devices and methods for measuring impedances at RF frequencies as such are known in the art. A measurement of the impedance of the impedance matching block is an indirect measurement, or at least an indication, of the impedance of the substrate. The impedance of the substrate changes as a material is deposited on the substrate. Thus, in an exemplary embodiment of a method as disclosed herein, an impedance of the matching block is calibrated to a layer thickness which is deposited on the substrate (211). Then, a material deposition step is ended after a pre-determined impedance of the matching block is detected, which corresponds to a point in time at which a pre-determined amount of material has been deposited on the substrate (211). Thus, the repeatability of a deposition process can be improved.

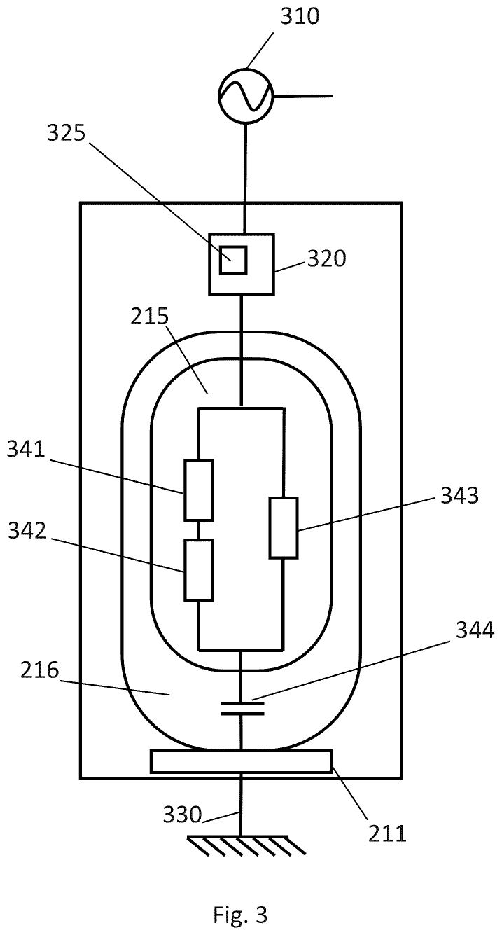

FIG. 3 shows an equivalent circuit of the components shown in FIG. 2. The plasma (215) can be modelled by means of two parallel branches: a first branch, and a second branch. The first branch comprises a plasma inductance (341) in series with a plasma capacitance (342). The second branch comprises a plasma resistance (343). The impedance of the plasma is in series with plasma sheath (216) having a sheath capacitance (344). The plasma sheath is in series with a substrate (211) which has its own (unknown) impedance. When material is deposited on the substrate, the substrate's impedance changes. In addition, the impedance of the plasma (215) and the plasma sheath (216) changes as material is deposited on the substrate (211). In some embodiments, the substrate (211) can be modelled as a time-varying capacitance in series with the capacitance of the plasma sheath. The substrate (211) is grounded by means of an electrical ground (330). The impedance changes caused by material deposition on the substrate require the plasma control and measurement unit (320) to continuously adapt a matching impedance in order to maintain matching of an RF power source (310) to the combined impedance of the plasma (215), the plasma sheath (216), and the substrate (211). Such matching techniques as such are well known in the art. The plasma control and memory unit (320) comprises a data acquisition module (325) which is configured for registering the matching impedance required for matching the RF power source (310) to the combined impedance of the plasma (215), the plasma sheath (216), and the substrate (211).

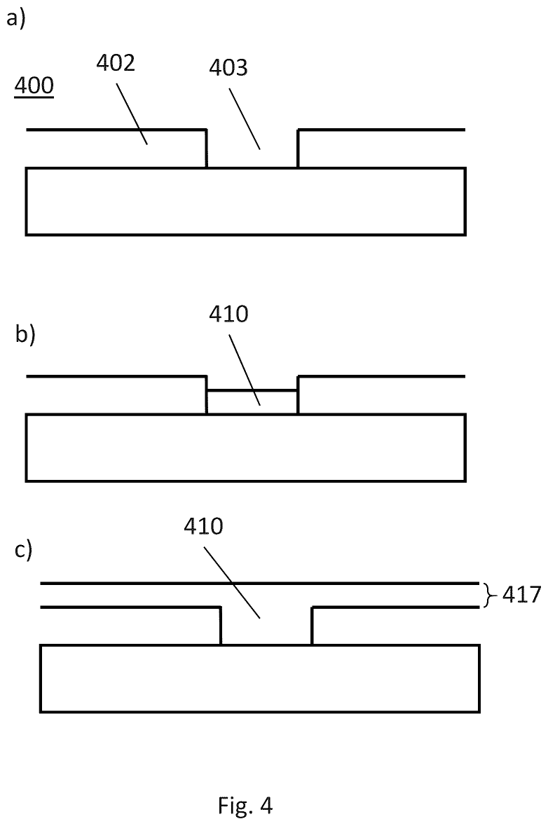

FIG. 4 shows three stages of a material deposition process that can be executed by means of a method as disclosed herein. In particular panel a) schematically depicts a substrate (400) comprising a patterned layer (402) having a recess (403) before a selective deposition process. Panel b) schematically depicts how a material layer (410) is selectively deposited in the recess (403). Panel c) schematically depicts how an overburden (417) forms while depositing the material layer (410). The formation of an overburden (417) can be hard to avoid, but methods and devices according to the present disclosure allow increasing the reproducibility of the overburden (417), thereby facilitating its removal.

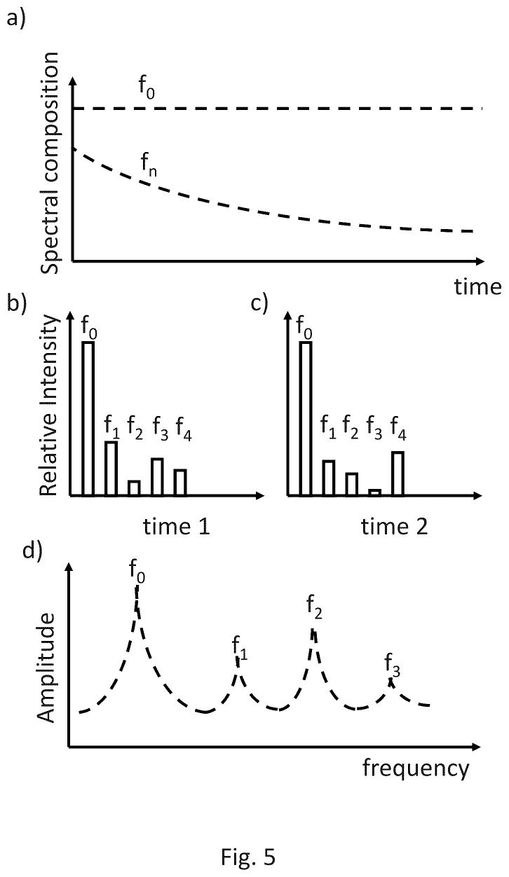

FIG. 5 comprises four panels: panel a), panel b), panel c), and panel d). Panel a) schematically shows how the spectral composition of the radio frequency signal by which the plasma is generated changes in time. In particular, it shows how the relative intensity of an nth overtone in the radio frequency signal gradually decreases with respect to the fundamental frequency of the radio frequency signal as a material layer is deposited on a substrate. In some embodiments, a pre-determined ratio of the intensity of the amplitude of an nth overtone with respect to the amplitude of the fundamental frequency can be used as a cut-off point to end a deposition process. Since this ratio corresponds to a specific amount of material that has been deposited on the substrate, process repeatability can be enhanced. Panel b) schematically shows discrete overtones in a frequency spectrum of the radio frequency signal by which the plasma is generated at the beginning of a deposition process. Panel c) schematically shows discrete overtones in a frequency spectrum of the radio frequency signal by which the plasma is generated at the end of a deposition process. Panel d) schematically shows a continuous frequency spectrum of the radio frequency signal, in which the overtones are labeled. In some embodiments, a ratio of any two amplitudes of different overtones can be used to detect the end of the deposition process. Alternatively, the relative amplitudes of the radiofrequency signal at a plurality of frequencies, or even in a continual frequency range, can be used for detecting the end point of the deposition process. In some embodiments, detecting the end point of the deposition process comprises detecting when the frequency spectrum of the radiofrequency spectrum matches a pre-determined spectrum up to within a pre-determined accuracy. Any pattern recognition or curve fitting method can be used for doing so.

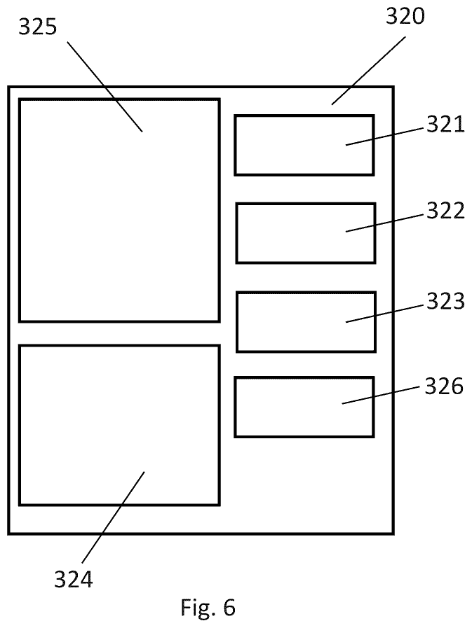

FIG. 6 schematically shows an exemplary embodiment of a plasma control and measurement unit (320). The plasma control and measurement unit (320) comprises an impedance matching module (324) having a matching impedance by which the impedance of the load (i.e plasma+plasma sheath+substrate) is matched to the impedance of the power source. The plasma control and measurement unit (320) further comprises a data acquisition module (325) that measures the radio frequency signal or a characteristic thereof by which the plasma is generated. In some embodiments, the data acquisition module (325) measures the spectral characteristics of the radio frequency signal in an indirect way, i.e., by measuring the matching impedance of the impedance matching module (324) used for matching the impedance of the load to that of the power source. Additionally or alternatively, the data acquisition module (325) can measure the radio frequency signal as such. Data measured by the data acquisition module (325) can be optionally stored in situ by means of a memory module (321) and/or processed in situ by means of a processor (323). The plasma control and measurement unit (320) further comprises a communication module (322) for communicating data with an external processing device. The thusly communicated data can comprise at least one of as-measured data and processed data. The plasma control and measurement unit (320) further comprises a switching module (326) which is operationally connected to the power source, and which is configured for switching the power source off, i.e., for stopping the plasma, based on a pre-determined stop criterion. The pre-determined stop criterion can be suitably stored in the memory module (321).

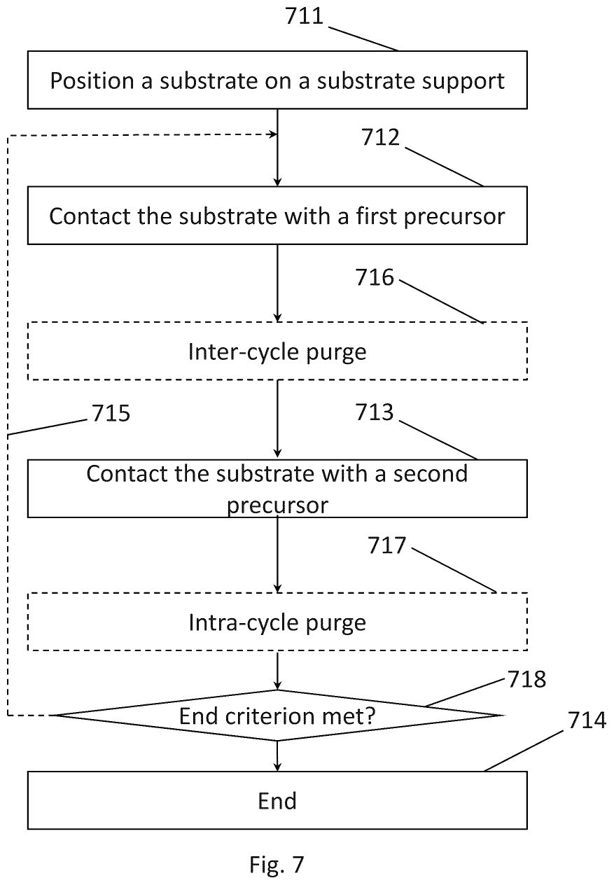

FIG. 7 illustrates an embodiment of a method for depositing a material on a substrate. The method employs a system as described herein and comprises positioning a substrate on a substrate support (711). Then, the method comprises cyclically executing one or more cycles (715), e.g., a plurality of cycles, e.g., 2, 5, 10, 20, 50, 100, 200, 500, 1000, 2000, 5000 or more cycles. A cycle comprises the following steps, in the following order: a step of contacting the substrate with a first precursor (712), and a step of contacting the substrate with a second precursor (713). At least one of the step of contacting the substrate with a first precursor (712) and the step of contacting the substrate with a second precursor (713) comprises generating a plasma in the reaction chamber. Optionally, the step of contacting the substrate with the first precursor and the step of contacting the substrate with the second precursor can be separated by an intra-cycle purge (716). Additionally or alternatively, subsequent cycles can, in some embodiments, be separated by an inter-cycle purge (717). In some embodiments, the plasma is on throughout the deposition process. In some embodiments, the plasma is pulsed, i.e., the plasma is only on during some of the steps or purges, and not during the other steps or purges. This cyclical deposition process results in the deposition of a material, e.g., a layer, on the substrate. The method comprises measuring one or more plasma parameters as described herein to determine whether or not a determined layer thickness has been deposited based on whether or not a pre-determined end criterion has been met (718). Exemplary end criterions are described elsewhere herein. As long as the end criterion has not been met, the cyclical deposition process is repeated (715). When the end criterion has been met, the cyclical deposition process ends (714).

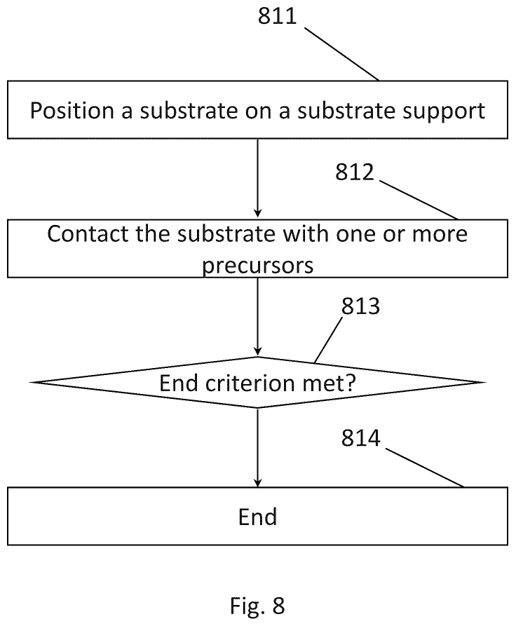

FIG. 8 illustrates a further embodiment of a method for depositing a material on a substrate as described herein. The method comprises a step of positioning a substrate on a substrate support (811). The method further comprises contacting the substrate with one or more precursors (812). Simultaneously, a plasma is generated in the reaction chamber. Thus, a material can be deposited on the substrate. When a desired amount of material has been deposited on the substrate, e.g. in the form of a layer having a pre-determined thickness, this is detected (813) by means of a method as described herein, and the plasma can be turned off, the precursor flow can be stopped, i.e. the substrate is no longer contacted with precursor, and the method ends (814).

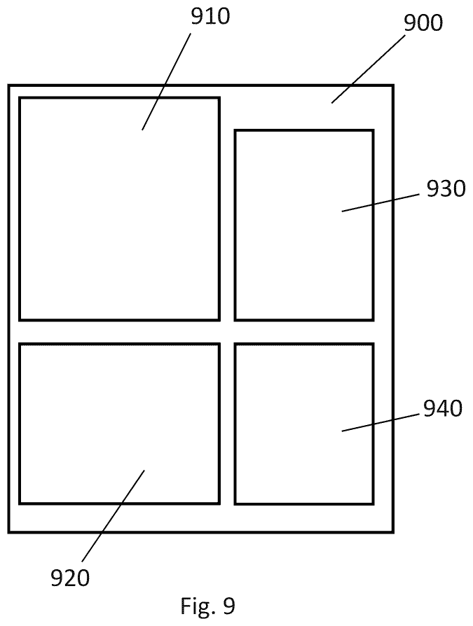

FIG. 9 schematically shows an exemplary embodiment of a plasma control and measurement unit (900). The plasma control and measurement unit (900) comprises a gas flow controlling unit (910), a memory (920), a plasma control and measurement unit (930), and a comparing unit (940). The gas flow controlling unit (910) is arranged to control gas flow into the gas injection system. The memory (920) is arranged to store a pre-determined plasma characteristic. The plasma control and measurement unit (930) is arranged for causing the system to generate a radio frequency plasma in the reaction chamber by means of the radio frequency power waveform. The plasma control and measurement unit (930) is further arranged to monitor the radio frequency plasma to obtain a monitored plasma characteristic. The comparing unit (940) is arranged to compare the monitored plasma characteristic with the pre-determined plasma characteristic stored in the memory. The plasma control and measurement unit (900) is programmed to end the deposition process when the comparing unit (940) indicates that the monitored plasma characteristic matches a pre-determined criterion. Suitably, the plasma control and measurement unit (900) can be further arranged for causing the system to carry out a method as disclosed herein.

The example embodiments of the disclosure described herein do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

1. A system comprising:
a reaction chamber, the reaction chamber comprising a substrate support and an upper electrode, the substrate support comprising a lower electrode;
a radio frequency power source arranged for generating a radio frequency power waveform;
a gas injection system fluidly coupled to the reaction chamber;
at least one gas source for introducing a precursor and optionally a carrier gas in the reaction chamber;
an exhaust; and
a controller comprising:
a gas flow controlling unit arranged to control gas flow into the gas injection system,
a memory arranged to store a pre-determined plasma characteristic;
a plasma control and measurement unit, the plasma control and measurement unit being arranged for causing the system to generate a radio frequency plasma in the reaction chamber by means of the radio frequency power waveform, and the plasma control and measurement unit being further arranged to monitor the radio frequency plasma, thereby obtaining a monitored plasma characteristic; and
a comparing unit arranged to compare the monitored plasma characteristic with the pre-determined plasma characteristic stored in the memory;
the controller being configured to end a deposition process when the comparing unit indicates that the monitored plasma characteristic matches a pre-determined criterion.

2. The system according to claim 1, wherein the controller is arranged for causing the system to carry out a method comprising:
position a substrate on the substrate support;
provide the precursor to the reaction chamber;
generate the radio frequency; and
using the plasma control and measurement unit, monitor the monitored plasma characteristic to determine whether or not a determined layer thickness has been deposited on the substrate,
wherein the monitored plasma characteristic comprises the radio frequency power waveform.

3. The system according to claim 2, wherein the pre-determined criterion comprises a spectral distribution of the radio frequency power waveform.

4. The system according to claim 2, wherein the deposition process is continuous and is ended when the monitored plasma characteristic matches the pre-determined criterion.

5. The system according to claim 1, wherein the upper electrode comprises a showerhead injector.

6. The system according to claim 5, wherein the showerhead injector is a dual channel showerhead injector comprising a first set of channels and a second set of channels.

7. The system according to claim 1, wherein the lower electrode is grounded, and wherein the upper electrode is electrically connected to the radio frequency power source and to the plasma control and measurement unit.

8. The system according to claim 1, further comprising a wall heater for heating a wall of the reaction chamber.

9. The system according to claim 1, wherein the substrate support comprises a heater.

10. The system according to claim 1, wherein the plasma control and measurement unit is located exterior the reaction chamber.

11. The system according to claim 3, wherein the spectral distribution of the radio frequency power waveform comprises a fundamental frequency and an nth overtone, the fundamental frequency having a fundamental frequency amplitude and the nth overtone having an nth overtone amplitude, and wherein the deposition process is ended when a ratio of the nth overtone amplitude and the fundamental frequency amplitude exceeds a pre-determined value.

12. The system according to claim 3, wherein the spectral distribution of the radio frequency power waveform comprises a fundamental frequency and an nth overtone, the fundamental frequency having a fundamental frequency amplitude and the nth overtone having an nth overtone amplitude, and wherein the deposition process is ended when a ratio of the fundamental frequency amplitude and the nth overtone amplitude exceeds a pre-determined value.

13. The system according to claim 1, wherein the monitored plasma characteristic comprises a monitored spectral distribution of the radio frequency power waveform, and wherein the pre-determined criterion comprises a similarity score calculated by (1) subtracting the spectral distribution of the radio frequency power waveform from the pre-determined spectral distribution and integrating this difference to obtain a similarity score or (2) subtracting a matching impedance from a pre-determined frequency-dependent reference impedance and integrating this difference to obtain a similarity score.

14. The system according to claim 13, wherein the controller is configured to end the deposition process when the similarity score as a function of time reaches a stationary point.

15. The system according to claim 1 wherein the monitored plasma characteristic comprises a matching impedance of an impedance matching block, wherein the impedance matching block is arranged for matching an impedance of the radio frequency power source to a load.

16. The system according to claim 15 wherein the matching impedance is frequency dependent, and wherein the pre-determined criterion comprises a similarity score calculated using the matching impedance and a pre-determined frequency-dependent reference impedance.

17. The system according to claim 13, wherein the controller is further configured to end a deposition process when an absolute value of a rate of change of the similarity score with time drops below a pre-determined value.

18. The system according to claim 1, wherein the pre-determined criterion comprises a similarity score calculated by subtracting the spectral distribution of the radio frequency power waveform from the pre-determined spectral distribution and integrating this difference to obtain a similarity score.

19. The system according to claim 1, further comprising a matching block, wherein a predetermined impedance of the matching block corresponds to the predetermined thickness.

20. The system according to claim 19, wherein the controller is configured to end the deposition process after the predetermined impedance of the matching block is detected.
